(19) United States
(12) Patent Application Publication
(10) Pub. No.: US 2009/0057825 A1
(43) Pub. Date: Mar. 5, 2009

(54) Semiconductor Device and a Method for Fabricating the Same

(76) Inventor: Nam Joo Kim, Yongin-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/199,499

(22) Filed: Aug. 27, 2008

(30) Foreign Application Priority Data
Aug. 28, 2007 (KR) 10-2007-0086501

(51) Int. Cl. H01L 29/00; H01L 21/02

(52) U.S. Cl. 257/531; 438/381; 257/E29.001; 257/E21.022

(57) ABSTRACT

A semiconductor device including an inductor and a fabricating method thereof are provided. The semiconductor device can include a connection wiring provided on a semiconductor substrate; a metal wiring provided on an insulating layer in a spiral shape and electrically connected to the connection wiring; and holes provided in the insulating layer and between the metal wiring and the silicon substrate.

### CROSS-REFERENCE TO RELATED APPLICATION

The present application claims the benefit under 35 U.S.C. §119 of Korean Patent Application No. 10-2007-0086501, filed Aug. 28, 2007, which is hereby incorporated by reference in its entirety.

### BACKGROUND

As technology in the field of radio mobile communications has become increasingly important, the need for high frequency resources and devices and circuits operating at high frequencies has increased. Such devices typically include a radio frequency (RF) part and an integrated circuit (IC).

Also, as technology in the field of semiconductor processing has been developed, the high frequency characteristics of a complementary metal-oxide semiconductor (CMOS) have greatly improved. Since a CMOS is based on silicon, it is possible to fabricate a low-cost chip using well developed process technologies, and it is also possible to integrate even an intermediate frequency band and a digital part of a system by using System On Chip (SOC) methodologies. Thus, a CMOS SOC is generally considered the most appropriate technology for fabricating a single chip.

RF IC technology includes of a combination of device fabrication technology, circuit design technology, and high frequency package technology. These technologies should be developed in balance to develop a competitive RF-CMOS device. Generally, reduction of fabrication cost is a driving factor. To this end, it is beneficial to simplify and stabilize fabrication processes. Main components of an RF CMOS or a bipolar/BiCMOS device are an RF metal oxide semiconductor field effect transistor (MOSFET), an inductor, a varactor, a metal-insulator-metal (MIM) capacitor, and a resistor.

An inductor typically consists of an insulating layer formed on a silicon substrate and a metal wiring formed on the insulating layer.

The insulating layer, which is generally a dielectric material interposed between the metal wiring and the silicon substrate, is one of the main causes of parasitic capacitance between the metal wiring and the silicon substrate.

As the parasitic capacitance increases, the efficiency and the use frequency band of the inductor decrease. Thus, there exists a need in the art for an improved semiconductor device and fabrication method thereof.

### BRIEF SUMMARY

Embodiments of the present invention provide improved semiconduct or devices and fabricating methods thereof. Such devices can be used for RF applications.

In an embodiment, a semiconductor device can comprise: a first insulating layer provided on a silicon substrate; a connection wiring provided on the first insulating layer; a second insulating layer provided on the first insulating layer and the connection wiring; a metal wiring provided on the second insulating layer in a spiral shape and electrically connected to the connection wiring; and at least two holes provided in the first insulating layer and the second insulating layer and between the metal wiring and the silicon substrate.

In another embodiment, a method for fabricating a semiconductor device can comprise: forming a first insulating layer on a silicon substrate; forming a connection wiring on the first insulating layer; forming a second insulating layer on the first insulating layer and the connection wiring; forming a via metal pattern in the second insulating layer and contacting the connection wiring; forming at least two holes in the first insulating layer and the second insulating layer; forming a sacrifice layer pattern inside the holes; forming a metal wiring on the sacrifice film pattern and the second insulating layer and contacting the via metal pattern; and removing the sacrifice layer pattern to form an air layer between the metal wiring and the silicon substrate.

Embodiments of the present invention can reduce parasitic capacitance by providing an air layer between a silicon substrate and a metal wiring of an inductor, thereby making it possible to expand the range of usable frequencies of an inductor.

Also, embodiments of the present invention can provide an inductor having a high Q factor, thereby enhancing an effective value of the inductor and the quality of an inductor used at a specific frequency.

### BRIEF DESCRIPTION OF THE DRAWINGS

FIG. 1 is a plan view showing an inductor of a semiconductor device according to an embodiment of the present invention.

FIG. 2 is a cross-sectional view of an inductor taken along line I-I′ of FIG. 1.

FIGS. 3 to 10 are cross-sectional views showing a method of fabricating an inductor of a semiconductor device according to an embodiment of the present invention.

FIG. 11 is a plan view of an inductor according to an embodiment of the present invention.

FIG. 12 is a plan view showing an inductor according to an embodiment of the present invention.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

Reference will now be made in detail to the embodiments of the present disclosure, examples of which are illustrated in the accompanying drawings.

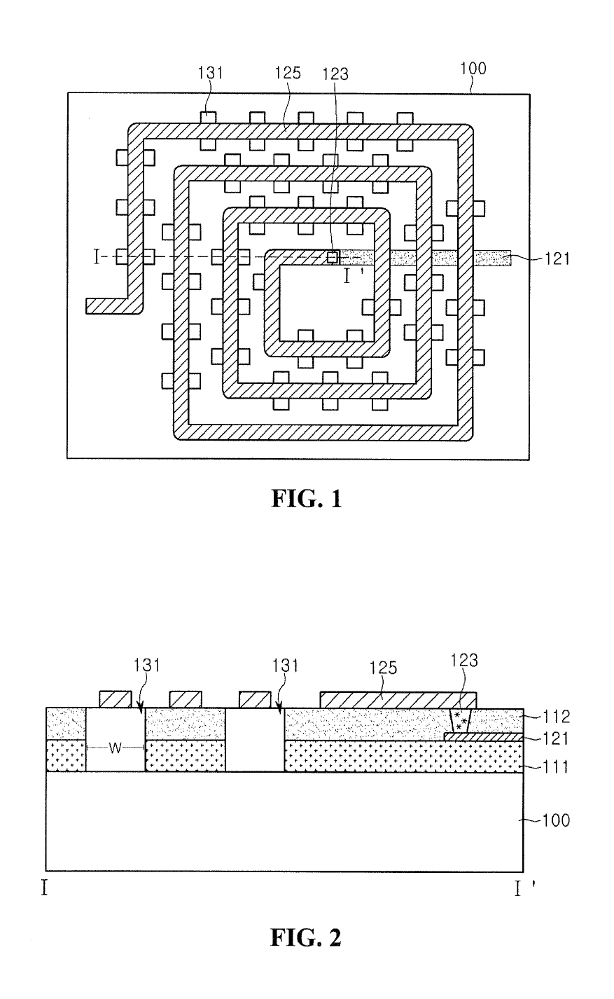

FIG. 1 is a plan view showing an inductor of a semiconductor device according to an embodiment of the present invention, and FIG. 2 is a cross-sectional view of an inductor taken along line I-I′ of FIG. 1.

An inductor according to embodiments of the present invention can be implemented upon any suitable semiconductor device. For example, the semiconductor device could be a complimentary metal oxide semiconductor (CMOS) device, an n-channel metal oxide semiconductor (NMOS) device, or a p-channel metal oxide semiconductor PMOS device.

Referring to FIG. 1, in an embodiment, an inductor can include a metal wiring 125, which can be formed in a spiral shape. For example, the metal wiring 125 can be formed in a spring shape or a coil shape as viewed from above the inductor (plan view). Specifically, the metal wiring 125 can be formed as a single wound element without gaps in the line of the inductor, and can have a spring or coil shape. The metal wiring 125 can have a spiral shape and can include several bends.

Referring to FIG. 2, a first insulating film 111 can be provided on a silicon substrate 100. A connection wiring 121 can be provided on the first insulating film 111, and the connection wiring 121 can be electrically connected to the metal wiring 125 through a via metal pattern 123.

A second insulating film 112 can be provided on the first insulating film 111 including the connection wiring 121.

The metal wiring 125 can be provided on the second insulating film 112.

In an embodiment, at least two holes 131 can be provided in the first insulating layer 111 and the second insulating layer 112 under the metal wiring 125 and above the silicon substrate 100. The holes 131 can provide an air layer between the metal wiring 125 and the silicon substrate 100.

The air layer can be provided within the holes 131, and the holes 131 can help reduce parasitic capacitance between the metal wiring 125 and the silicon substrate 100.

Referring again to FIG. 1, in certain embodiments, the holes 131 can be arranged at a predetermined interval along the metal wiring 125.

In an embodiment, the holes can be provided such that they can extend past the width of the metal wiring 125, as viewed from above.

In one embodiment, the width W of each hole 131 can be from about 1 μm to about 5 μm

The width of the holes 131 can be larger than that of the metal wiring 125 such that portions of the holes 131 can be exposed.

The holes 131 can have any suitable shape known in the art, for example, an approximately square shape, an approximately rectangular shape, an approximately oval shape, or an approximately circular shape.

The metal wiring can be electrically connected to the connection wiring 121 through a via metal pattern 123 such that the connection wiring 121 can apply an electrical signal to the metal wiring 125. In an embodiment, a terminal of the metal wiring 125 can be an output terminal of the inductor.

In one embodiment, the holes 131 formed below the metal wiring 125 can be offset from the holes 131 formed below an adjacent line of the metal wiring 125. Accordingly, adjacent lines of the metal wiring 125 can be provided closer together, thereby reducing the size of the semiconductor device.

Inductors according to embodiments of the present invention can have a high Q factor, thereby enhancing an effective value of the inductor and the quality at specific frequencies.

Though two insulating layers have been depicted for purposes of illustration, a skilled artisan would readily recognize that more or less insulating layers could be present within the scope of the present invention.

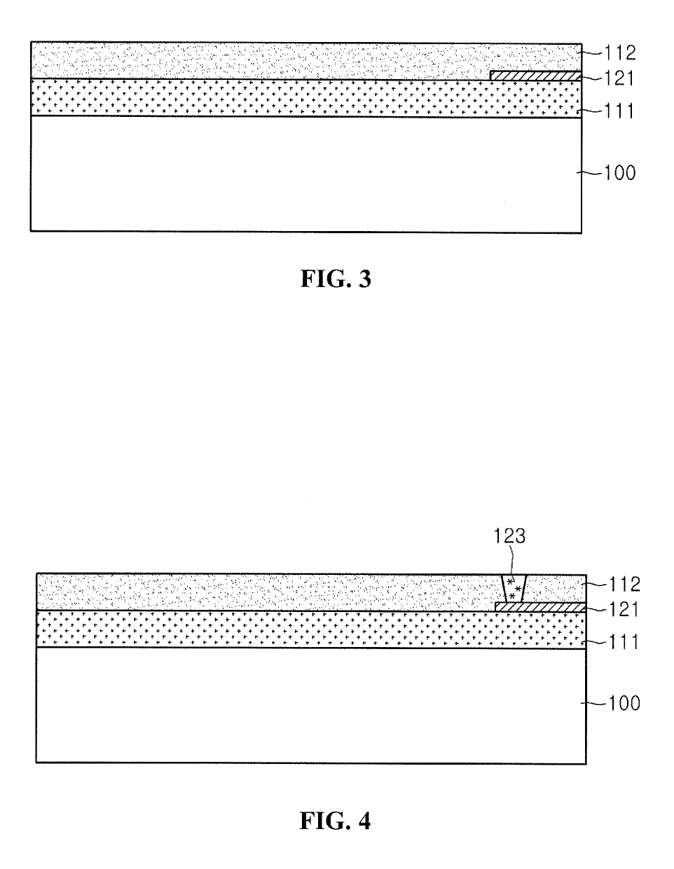

FIGS. 3 to 10 are cross-sectional views showing a method of fabricating an inductor of a semiconductor device according to an embodiment of the present invention.

Referring to FIG. 3, a first insulating layer 111 can be formed on the silicon substrate 100.

A connection wiring 121 can be formed on the first insulating layer 111. The connection wiring 121 can be formed of any suitable material known in the art, such as aluminum. The connection wiring 121 can subsequently be electrically connected to an output terminal of the inductor. In an embodiment, the connection wiring 121 can be the output terminal of the inductor.

A second insulating layer 112 can be formed on the first insulating layer 112 including the connection wiring 121.

Referring to FIG. 4, a via hole exposing at least a portion of the connection wiring 121 can be formed in the second insulating layer 112, and a via metal pattern 123 electrically connected to the connection wiring 121 can be formed in the via hole. The via metal pattern 123 can be formed of any suitable material known in the art, such as tungsten.

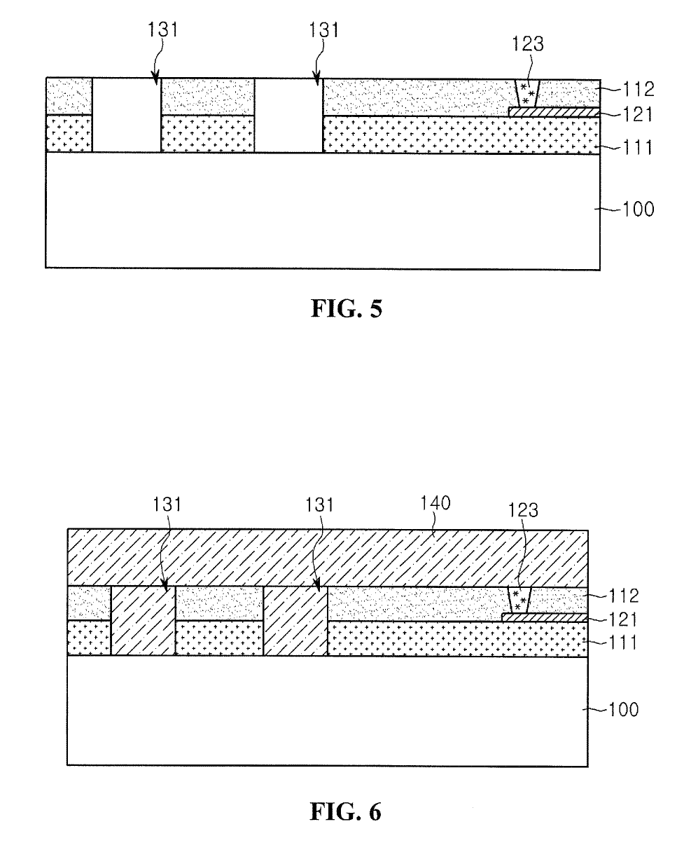

Referring to FIG. 5, holes 131 can be formed in the second insulating layer 112 and the first insulating layer 111. In certain embodiments, the holes 131 can be arranged in a predetermined interval.

In an embodiment, the holes 131 can be formed at positions where a metal wiring 125 for forming the inductor can subsequently be formed.

Referring to FIG. 6, an organic layer 140 can be formed on the second insulating layer 112 and in the holes 131. In an embodiment, the organic layer 140 can have a low dielectric constant.

The organic layer 140 can be removed, as described in more detail below, before the inductor device is completed. Thus, the organic layer 140 can be used as a sacrifice layer.

The organic layer 140 can be formed of any suitable material known in the art, for example, a polyimide or a photoresist material. In an embodiment, the dielectric constant of the organic layer 140 can be smaller than that of the first insulating layer 111 and the second insulating layer 112. In an alternative embodiment, the dielectric constant of the organic layer 140 can be the same as that of the first insulating layer 111 and/or that of the second insulating layer 112. In yet another embodiment, the dielectric constant of the organic layer 140 can be larger than that of the first insulating layer 111 and the second insulating layer 112.

The holes can be filled by the organic layer 140

The organic layer 140 can be formed by any suitable method known in the art, for example, by a coating method. For embodiments utilizing a photoresist as the organic layer 140, a hardening process can be performed after coating the photoresist on the second insulating layer 112 and in the holes 131. According to an embodiment, a developing process is not performed after hardening the photoresist.

Thereafter, the organic layer 140 can be polished to expose the second insulating layer 112. Any suitable polishing method can be used, for example, a chemical mechanical polishing (CMP) process can be used.

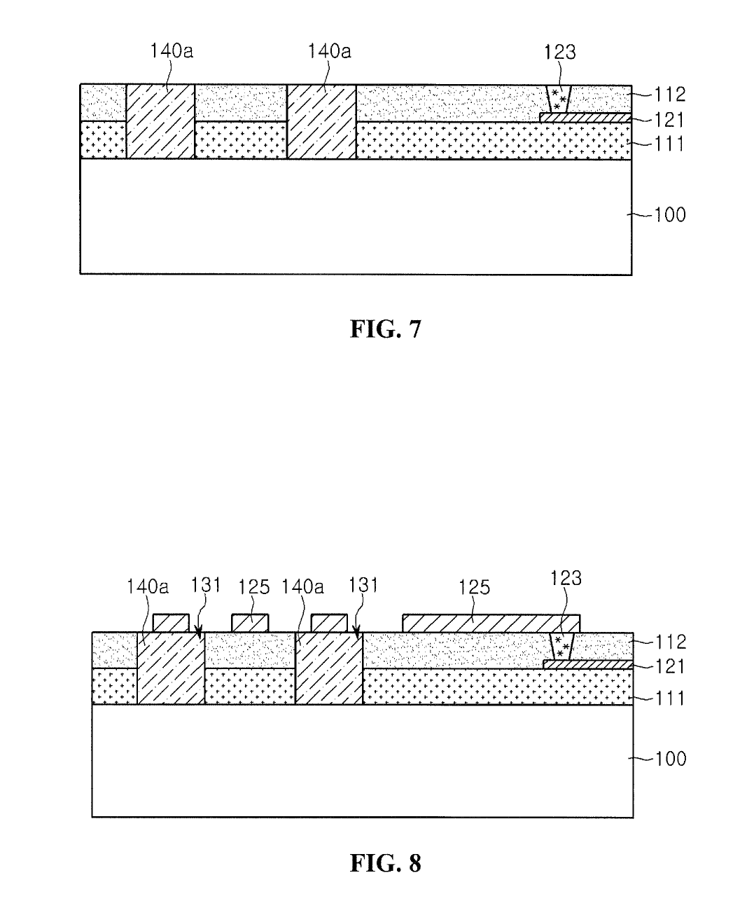

Referring to FIG. 7, an organic layer pattern 140a filled in the holes 131 can be formed from the organic layer 140.

Referring to FIG. 8, a metal layer can be formed on the second insulating layer 112 and the organic pattern 140a and then patterned, thereby forming the metal wiring 125.

In an embodiment, the metal wiring 125 can be formed in a spiral form. For example, the metal wiring 125 can include straight unit wirings connected with bending parts to give a spiral shape.

The metal wiring 125 can contact the via metal pattern 123 so that they are electrically connected to each other.

In an embodiment, the metal wiring 125 can be patterned such that the width of each hole 131 is larger than that of the metal wiring 125.

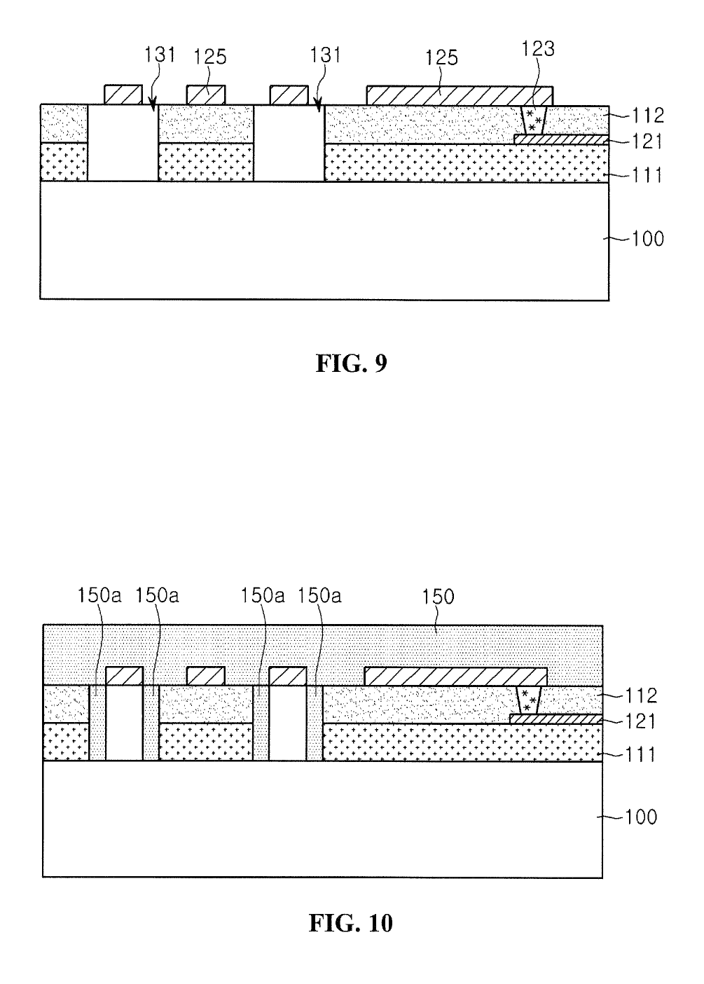

Referring to FIG. 9, the organic layer pattern 140a can be removed. The organic layer pattern 140a can be removed by any suitable process known in the art. In one embodiment, the silicon substrate 100 can be dipped into a wet etching solution for removing the organic layer pattern 140a, or the wet etching solution can be sprayed on the silicon substrate 100, thereby removing the organic pattern 140a.

Accordingly, the metal wiring 125 can be provided across the holes 131 such that an air layer is provided between the metal wiring 125 and the silicon substrate 100.

Referring to FIG. 10, in an embodiment, a third insulating layer 150 can be formed on the second insulating layer 112 and the metal wiring 125.

In certain embodiments, the third insulating layer 150 can fill in a portion of the holes 131. The third insulating layer 150 fills in a portion of the holes 131 exposed to the sides of the metal wiring 125, thereby forming a third insulating layer pattern 150a.

In an embodiment, a portion of the third insulating layer 150 can be removed to expose the metal wiring 125. At least a majority of the third insulating layer pattern 150a in the holes 131 can remain after a portion of the third insulating layer 150 has been removed to expose the metal wiring 125.

The first insulating layer 111, the second insulating layer 112, and the third insulating layer 150 can each be formed of any suitable material known in the art, for example, an oxide film.

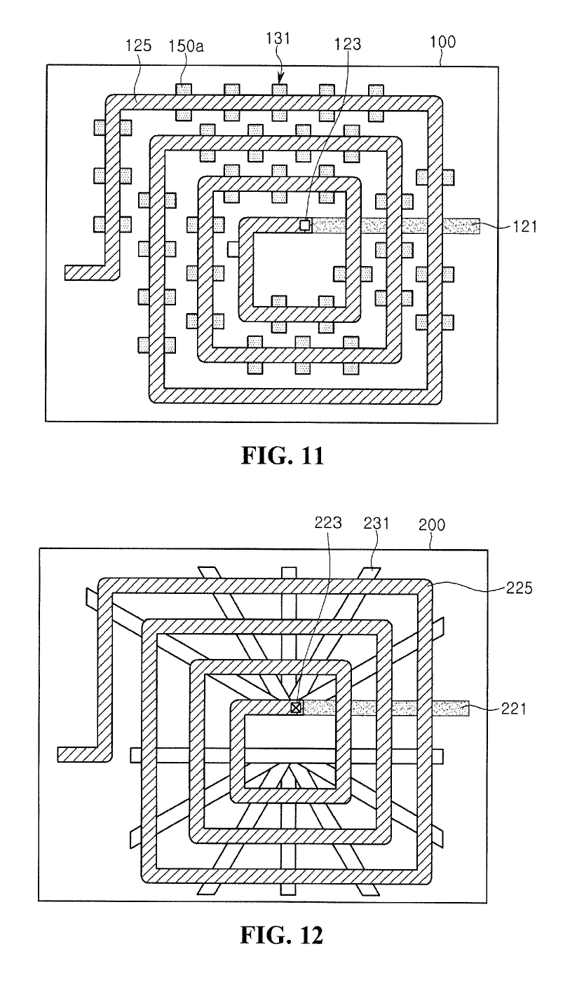

FIG. 11 is a plan view of an inductor according to an embodiment of the present invention.

Referring to FIG. 11, in an embodiment, the third insulating layer pattern 150a can be provided in the holes 131 and exposed on the sides of the metal wiring 125, as viewed from above.

A portion of the holes 131 can be filled with the third insulating layer pattern 150a, and the remaining portion of the holes 131 below the metal wiring 125 can be empty to provide the air layer.

The air layer can be completely surrounded by the metal wiring 125, the third insulating layer pattern 150a, and the silicon substrate 110.

The third insulating layer pattern 150a can be formed on a portion of the side walls of the first insulating layer 111 and the second insulating layer 112 within the holes 131.

FIG. 12 is a plan view showing an inductor according to a another embodiment of the present invention.

A connection wiring 221 electrically connected to the inductor can be provided on a silicon substrate 200, and one or more insulating layers (not shown) can be provided between the connection wiring 221 and the silicon substrate 200.

One or more insulating layers (not shown) can also be provided on the connection wiring 221.

A metal wiring 225 can be provided on the connection wiring 221 and electrically connected to the connection wiring 221. One or more insulating layers (not shown) can be provided between the metal wiring 225 and the connection wiring 221.

The metal wiring 225 can be formed in a spiral shape. For example, the metal wiring 225 can be formed in a spring shape or a coil shape as viewed from above. Specifically, the metal wiring 125 can be formed as a single wound element without gaps in the line of the inductor, and can have a spring or coil shape. The metal wiring 125 can have a spiral shape and can include several bends.

Instead of the holes 131, a trench pattern 231 can be formed in the one or more insulating layers (not shown) between the metal wiring 225 and the silicon substrate 200.

The trench pattern 231 can be formed in any suitable shape, including a radial shape. The trench pattern 231 can be formed across the metal wiring 225, and can include a straight trench and/or a curved trench.

An air layer can be formed in the trench pattern 231, providing a space between the metal layer 225 and the semiconductor substrate 200. The trench pattern 231 can reduce parasitic capacitance between the metal wiring 225 and the silicon substrate 200.

The metal wiring 225 can be electrically connected to the connection wiring 221 through a via metal pattern 223 such that the connection wiring 221 can apply an electrical signal to the metal wiring 225. A terminal of the metal wiring 225 can be an output terminal of the inductor.

Embodiments of the present invention can form an air layer between the metal wiring and the silicon substrate for the inductor to help reduce parasitic capacitance, thereby expanding the range of usable frequencies. The inductor can have a high Q factor, thereby enhancing an effective value of the inductor and the quality of an inductor used at a specific frequency.

An inductor according to embodiments of the present invention can be formed during a fabrication process of a semiconductor device. The semiconductor device can be any suitable semiconductor device known in the art, for example, a CMOS device, an NMOS device, or a PMOS device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a first insulating layer provided on a silicon substrate;
a connection wiring provided on the first insulating layer;
a second insulating layer provided on the first insulating layer and the connection wiring;
a metal wiring provided on the second insulating layer in a spiral shape and electrically connected to the connection wiring; and
at least two holes provided in the first insulating layer and the second insulating layer and disposed under the metal wiring between the metal wiring and the silicon substrate.

2. The semiconductor device according to claim 1, wherein a width of each hole is larger than that of the metal wiring.

3. The semiconductor device according to claim 1, wherein the holes are arranged below the second wiring at intervals along the length direction of the second wiring.

4. The semiconductor device according to claim 1, wherein the width of each hole is from about 1 μm to about 5 μm.

5. The semiconductor device according to claim 1, further comprising a radial trench pattern, wherein the at least two holes are a part of the radial trench pattern.

6. The semiconductor device according to claim 1, wherein a third insulating layer pattern is provided in a portion of each hole.

7. The semiconductor device according to claim 7, wherein the third insulating layer pattern, the metal wiring, and the semiconductor substrate form a completely enclosed air layer in each hole.

8. The semiconductor device according to claim 1, further comprising a via metal pattern, wherein the via metal pattern is in contact with the metal wiring and the connection wiring.

9. The semiconductor device according to claim 1, wherein holes of the at least two holes provided under a first section of the metal wiring are offset from holes of the at least two holes provided in an adjacent section of the metal wiring.

10. A method of fabricating a semiconductor device, comprising:
forming a first insulating layer on a silicon substrate;
forming a connection wiring on the first insulating layer;
forming a second insulating layer on the first insulating layer and the connection wiring;
forming a via metal pattern in the second insulating layer and contacting the connection wiring;
forming at least two holes penetrating through the first insulating layer and the second insulating layer;
forming a sacrifice layer pattern inside the holes;
forming a metal wiring on the sacrifice layer pattern and the second insulating layer, the metal wiring contacting the via metal pattern; and
removing the sacrifice layer pattern to form an air layer between the metal wiring and the silicon substrate.

11. The method according to claim 10, wherein the metal wiring has a spiral shape wound at least one time.

12. The method according to claim 10, wherein the sacrifice layer pattern comprises an organic layer.

13. The method according to claim 12, wherein the dielectric constant of the organic layer is smaller than that of the first insulating layer and that of the second insulating layer.

14. The method according to claim 10, wherein a width of each hole is larger than that of the metal wiring.

15. The method according to claim 10, wherein removing the sacrifice layer pattern comprises removing the sacrifice layer pattern until the semiconductor substrate is exposed.

16. The method according to claim 10, further comprising:
forming a third insulating layer on the second insulating layer and the metal wiring after removing the sacrifice layer pattern.

17. The method according to claim 16, wherein a portion of the third insulation layer fills in a portion of each hole.

18. The method according to claim 17, wherein the air layer within each hole is completely surrounded by the third insulation layer, the metal wiring, and the semiconductor substrate.

19. The method according to claim 10, wherein forming the at least two holes comprises forming a radial trench pattern in the first insulating layer and the second insulating layer, wherein the at least two holes are part of the radial trench pattern.

20. The method according to claim 19, wherein a width of the radial trench is larger than that of the metal wiring.
